(19) United States
(12) Patent Application Publication
(10) Pub. No.: US 2016/0157344 A1
(43) Pub. Date: Jun. 2, 2016

(54) STRUCTURE OF CONDUCTIVE LINES AND METHOD OF MANUFACTURING THE SAME

(71) Applicant: INDUSTRIAL TECHNOLOGY RESEARCH INSTITUTE, Hsinchu (TW)

(72) Inventors: Yu-Ming WANG, Hsinchu City (TW); Sheng-Yu LIN, Zhunan Township (TW); Wei-Yuan CHEN, Taichung City (TW); Kai-Jiun WANG, Tianwei Township (TW)

(21) Appl. No.: 14/583,467

(22) Filed: Dec. 26, 2014

(30) Foreign Application Priority Data
Nov. 28, 2014 (TW) 103141353

(51) Int. Cl. H05K 1/09; H05K 3/18; H05K 1/03

(52) U.S. Cl. CPC H05K 1/09; H05K 1/0313; H05K 3/182; H05K 3/188; H05K 3/185; H05K 2201/0326; H05K 2201/0364; H05K 2203/0716; H05K 2203/1105; H05K 2203/10

(57) ABSTRACT

A structure of conductive lines and method of manufacturing the same are disclosed by forming a patterned catalyst material layer on a substrate, activating the patterned catalyst material layer and growing a conductive layer on the patterned catalyst material layer. The pattern of the conductive layer corresponds to that of the patterned catalyst material layer. The patterned catalyst material layer and the conductive layer formed thereon constitute the structure of conductive lines of the embodiment. The structure of the conductive line of the disclosure has the characteristics of high conductivity. According to the embodiment, the catalyst material layer includes at least 40 wt %˜90 wt % of polymer and 10 wt %˜60 wt % of catalyzer. The catalyzer comprises one or more materials selected from organic-metallic compounds, metal particles, or a combination thereof.

This application claims the benefit of Taiwan application Serial No. 103141353, filed Nov. 28, 2014, the subject matter of which is incorporated herein by reference.

### TECHNICAL FIELD

The disclosure relates to a structure of conductive lines and method of manufacturing the same.

### BACKGROUND

Printed electronic products have great potential of development in the future market, and the feature of those printed electronic products in common is the continual decrease in the overall sizes. Size of each component equipped in the printed electronic product has to be restrictedly limited in order to satisfy the product requirements of being compact in size and lighter in weight in the market. Take the conductive lines for example, which are the most commonly used component in the printed electronic product. The line widths of the conductive lines have been reduced from couple hundreds micrometers to several micrometers. The derived theme is the perennial issue of process ability and production cost. The printing technology can be rapid and continuous processing, low power consumption and low pollution, which is regarded as the advanced technology for manufacturing the electronic product of the next generation. To deal with the trend of the size reduction of the printed electronic product, it would be very important that consideration is given to both the decrease of line width and the improvement of the electrical characteristics of the printed conductive lines.

### SUMMARY

The disclosure relates to a structure of conductive lines and method of manufacturing the same. The structure of conductive lines of the embodiment can be obtained by forming a patterned catalyst material layer as the trace pattern by printing process, activating the patterned catalyst material layer, followed by growing a conductive layer on the patterned catalyst material layer. The structure of conductive lines of the embodiment possesses high conductivity. Accordingly, the electronic products applied with the structure of conductive lines of the embodiment possess several advantages, such as good and stable conductivity of conductive lines, high yield of production and low-production cost. Also, the manufacturing method adopts rapid and low-pollution procedures.

According to one embodiment, a structure of conductive lines is provided, comprising a patterned catalyst material layer formed on a substrate, and the patterned catalyst material layer at least comprising 40 wt % to 90 wt % of polymer and 10 wt % to 60 wt % of catalyzer; and a conductive layer formed on the patterned catalyst material layer, and a pattern of the conductive layer corresponding to the patterned catalyst material layer, wherein the patterned catalyst material layer and the conductive layer formed thereon constitute the structure of the conductive lines, and the catalyzer comprises one or more materials selected from organic-metallic compounds, metal particles, or a combination thereof.

According to one embodiment, a method of manufacturing a structure of conductive lines is provided, comprising providing a substrate; forming a patterned catalyst material layer on the substrate, and the patterned catalyst material layer at least comprising 40 wt % to 90 wt % of polymer and 10 wt % to 60 wt % of catalyzer, wherein the catalyzer comprises one or more materials selected from organic-metallic compounds, metal particles, or a combination thereof; activating the patterned catalyst material layer; and contacting metal ions as provided to the patterned catalyst material layer, and a conductive layer being formed on the patterned catalyst material layer.

The disclosure will become apparent from the following detailed description of the preferred but non-limiting embodiments. The following description is made with reference to the accompanying drawings.

### BRIEF DESCRIPTION OF THE DRAWINGS

FIG. 1 is a method of manufacturing of a structure of conductive lines according to the embodiment of the disclosure.

FIG. 2 illustrates a method of manufacturing of a structure of conductive lines by a gravure offset printing process according to an embodiment of the disclosure.

FIG. 3 is a method of manufacturing of a structure of conductive lines according to one of the embodiments.

FIG. 4 illustrates a structure of conductive lines manufactured according to a method of the embodiment of the disclosure.

FIG. 5 shows the relationship of conductivity versus cross-sectional area of the conductive lines manufactured by the photolithography process, the printing process and the embodied manufacturing method.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Below, exemplary embodiments of organic light emitting devices will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

The exemplary embodiments of the disclosure are directed to a structure of conductive lines and method of manufacturing the same. The conductive lines of the embodiment can be obtained by forming a patterned catalyst material layer having a trace pattern using printing process (such as a gravure offset printing process), and then growing a dense conductive layer at the patterned catalyst material layer directly. Therefore, the conductive lines of the embodiment possesses high conductivity and high yield of production (i.e. since no notch defect typically occurs in the photolithography process would be shown in the structure of the embodiment, the problem of disconnection lines can be successfully solved), so that the electronic product applied with the structure of conductive lines of the embodiment possesses good and stable conductivity. Also, method of manufacturing the structure of conductive lines of the embodiment is simple, and adopts low-pollution and low-production cost procedures, which is suitable for mass production.

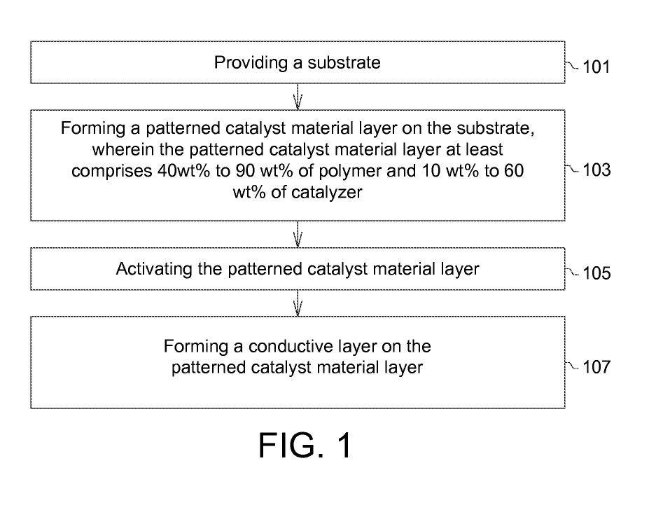

FIG. 1 is a method of manufacturing of a structure of conductive lines according to the embodiment of the disclosure. In step 101, a substrate is provided. A patterned catalyst material layer is formed on the substrate, such as printing related material by a gravure offset printing process, and the patterned catalyst material layer at least comprises 40 wt % to 90 wt % of polymer and 10 wt % to 60 wt % of catalyzer, as shown in step 103. The catalyzer may comprise one or more materials selected from organic-metallic compounds, metal particles, or a combination thereof. Then, the patterned catalyst material layer is activated, as shown in step 105. Afterward, a conductive layer is formed on the patterned catalyst material layer via the activated patterned catalyst material layer, as shown in step 107. In step 107, at least one kind of the metal ions is provided to be in contact with the patterned catalyst material layer, resulting in a conductive layer being formed on the patterned catalyst material layer. Also, a boundary exists between the patterned catalyst material layer and the conductive layer. In the embodiment, the conductive layer can be formed on the patterned catalyst material layer by electroplating or electroless plating (/chemical plating). According to the embodiment, the structure of conductive lines comprises a patterned catalyst material layer comprising polymer and catalyzer formed on a substrate, and a conductive layer (such as a dense metal) formed on the patterned catalyst material layer. Compared to the typical conductive lines formed by the photolithography process (i.e. a dense metal directly formed on the substrate, or a dense metal formed on the adhesion layer) and by a general printing process (i.e. a conductive layer comprising a mixture of the conductive particles and polymer formed on the substrate), the conductive lines of the embodiment possesses completely different structure.

Embodiments are provided hereinafter with reference to the accompanying drawings for describing the related configurations and procedures, but the present disclosure is not limited thereto. It is noted that not all embodiments of the disclosure are shown. Structures and manufacturing procedures of the embodiments would be different, and could be modified and changed optionally according to the design needs of the application. Modifications and variations can be made without departing from the spirit of the disclosure to meet the requirements of the practical applications. Thus, there may be other embodiments of the present disclosure which are not specifically illustrated. It is also important to point out that the illustrations may not be necessarily be drawn to scale. Thus, the specification and the drawings are to be regard as an illustrative sense rather than a restrictive sense.

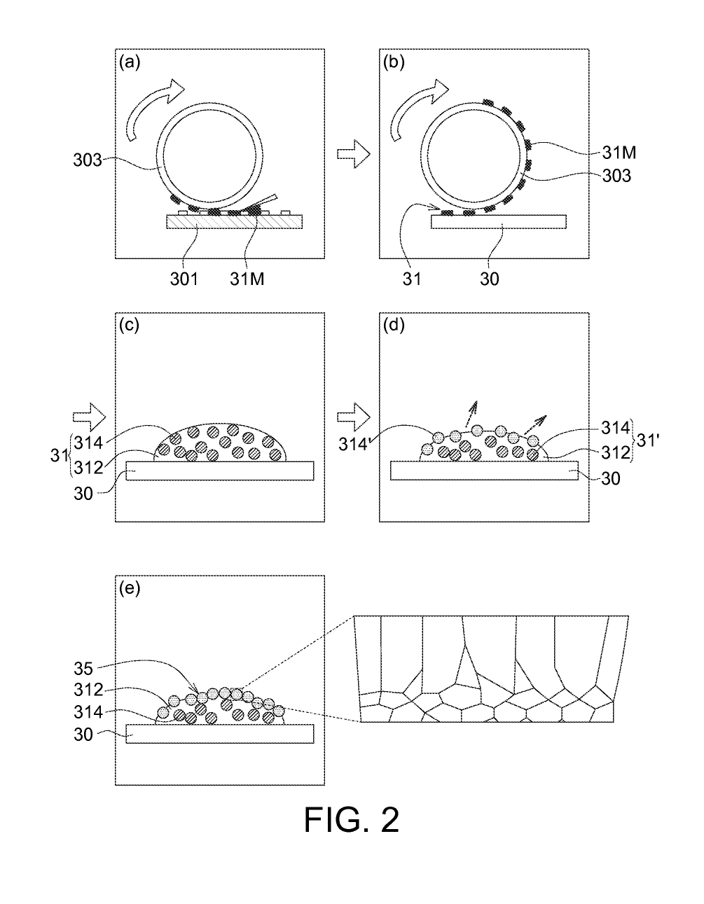

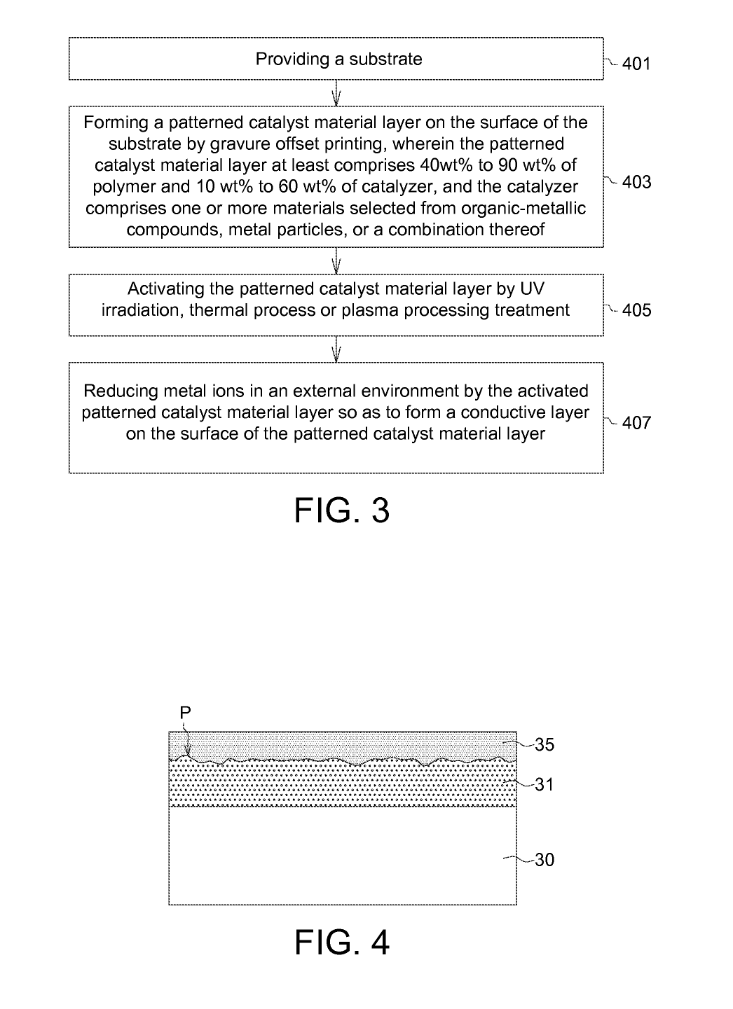

FIG. 2 illustrates a method of manufacturing of a structure of conductive lines by a gravure offset printing process according to an embodiment of the disclosure. FIG. 3 is a method of manufacturing of a structure of conductive lines according to one of the embodiments. Please refer to FIG. 2 and FIG. 3.

In one embodiment, after a substrate is provided as shown in step 401, the catalyst material as prepared is printed on the surface of the substrate by gravure offset printing to form a patterned catalyst material layer, and the patterned catalyst material layer at least comprises 40 wt % to 90 wt % of polymer and 10 wt % to 60 wt % of catalyzer, as shown in step 403. Please refer to FIG. 2. In the gravure offset printing process, the catalyst material 31 M as prepared is filled into the grooves of a gravure plate 301, and transferred to a transferring medium 303 such as a blanket roll for picking up the catalyst material 31M (step (a)), and then printed onto the surface of the substrate 30 to form a patterned catalyst material layer 31 (step (b)).

In one embodiment, the catalyst material 31M comprises 40 wt % to 90 wt % of polymer and 10 wt % to 60 wt % of catalyzer. The catalyst material 31M is printed onto the surface of the substrate 30 through the transferring medium 303.

In one embodiment, the patterned catalyst material layer 31 is a gelatinous layer, comprises 40 wt % to 90 wt % of polymer and 10 wt % to 60 wt % of catalyzer. The polymer 312 of the patterned catalyst material layer 31 may comprise one or more materials selected from acrylate resin, epoxy resin, phenol resin, or a combination thereof. In one embodiment, the catalyzer 314 of the patterned catalyst material layer 31 may comprise one or more materials selected from organic-metallic compounds, metal particles (/metallic granules), or a combination thereof. In one embodiment, the catalyzer 314 may comprise silver acetate, copper particles (/granules), silver particles (/granules), or a combination thereof. However, the present disclosure has no particular limitation to the materials described herein. Other polymer materials suitable for the gravure offset printing process and capable of being well-mixed with the selected catalyzer can be applied in the embodiment of the disclosure. Also, other catalyzer materials capable of being activated by appropriate treatment for reducing metal ions to generate a metal layer can be applied in the embodiment of the disclosure. Those materials as described have been provided for exemplification, not for limitation of the disclosure.

Subsequently, the patterned catalyst material layer 31 is activated by UV irradiation, thermal process (heating treatment/heating process), or plasma processing treatment, as shown in step (c) of FIG. 2 and step 405 of FIG. 3. The patterned catalyst material layer 31 is activated to form the activated catalysts 314′, as shown in step (d) of FIG. 2. Also, the arrows shown in step (d) denote gas produced in the activation, such as hydrocarbon, carbon dioxide, carbon monooxide, water and hydrogen chloride.

In addition to the mixture of the polymer 312 and the catalyzer 314 of the patterned catalyst material layer 31 on the substrate 30, other additives can be added into the mixture, depending on the method of activating treatment, the characteristics of the patterned catalyst material layer 31, and/or other factors. For examples, if the patterned catalyst material layer 31 is activated by UV irradiation in one embodiment, a photoinitiator is added into the patterned catalyst material layer 31. Additionally, if the patterned catalyst material layer 31 is activated by a thermal process in one embodiment, a heating treatment such as heating at a high temperature can be adopted for activating the patterned catalyst material layer 31, wherein the heating temperature and time are determined according to the practical materials of the polymer 312 and the catalyzer 314.

Furthermore, in one embodiment, a surface tension of the catalyst material 31M is a range of 20 mN/m to 40 mN/m, and this catalyst material 31M is suitable for the gravure offset printing process. In the catalyst material 31M, the polymer material having a surface tension near to or in the range of 20 mN/m to 40 mN/m can be selected for being the polymer 312 of the embodiment; however, it has no limitation thereto. In other embodiment, if the polymer 312 as selected has a surface tension off this range, an adequate surface tension additive can be added for adjusting the surface tension of the mixture of the catalyst material 31M to be suitable for use in the gravure offset printing process. Also, a viscosity modifier can be optionally added into the mixture of the catalyst material 31M, for adjusting the viscosity of catalyst material 31M to be suitable for use in the gravure offset printing process.

Subsequently, an external environment with metal ions is provided for the activated patterned catalyst material layer 31′. For example, at least one kind of the metal ions is provided to be in contact with the patterned catalyst material layer 31′, so that a conductive layer 35 is formed on the patterned catalyst material layer 31′. As shown in step (e) of FIG. 2 and step 407 of FIG. 3, the metal ions in the external environment are reduced by the activated patterned catalyst material layer 31′, so that a conductive layer 35 is formed on a surface of the activated patterned catalyst material layer 31′. Take an external environment containing copper sulfate (CuSO₄) and formaldehyde (CH₂O) for example. In step (e), copper sulfate (CuSO₄) and formaldehyde (CH₂O) are reduced by the activated patterned catalyst material layer 31′ to form a dense conductive layer 35 (such as copper) and sulfate ions (SO₄⁻) and formate ions (HCOOH) as produced. In one embodiment, the substrate 30 with the activated patterned catalyst material layer 31′ thereon is immersed into a plating solution for conducting an electroplating reaction or an electroless plating(/chemical plating) reaction, so as to reduce the metal ions in the plating solution and grow a dense conductive layer (i.e. a dense metal layer which is formed continuously and possessing high conductivity as pure metal does) on the surface of the patterned catalyst material layer. In one embodiment, the plating solution comprises copper sulphate, and a dense copper layer is grown on the surface of the patterned catalyst material layer.

FIG. 4 illustrates a structure of conductive lines manufactured according to a method of the embodiment of the disclosure. According to a manufacturing method of the embodiment, a structure of conductive lines comprises a substrate 30, a patterned catalyst material layer 31 formed on the substrate 30, and a conductive layer 35 formed on the patterned catalyst material layer 31. A pattern of the conductive layer 35 corresponds (ex: being substantially identical) to the patterned catalyst material layer 31, and the patterned catalyst material layer 31 at least comprises 40 wt % to 90 wt % of polymer 312 and 10 wt % to 60 wt % of catalyzer 314, wherein the catalyzer comprises one or more materials selected from organic-metallic compounds, metal particles, or a combination thereof. In one embodiment, a boundary P exists between the patterned catalyst material layer 31 and the conductive layer 35, and the boundary is substantially a flat surface. In one embodiment, the boundary P is substantially parallel to a surface of the substrate 30. Also, in one embodiment, a surface tension of the patterned catalyst material layer 31 is in a range of 20 mN/m to 40 mN/m, and the patterned catalyst material layer 31 can be formed on the surface of the substrate 30 by gravure offset printing the catalyst material 31M. According to the manufacturing method of the embodiment, the conductive lines with high conductivity can be obtained, and the line widths of the conductive lines can be larger than 0 μm and equal to or smaller than 30 μm. In one embodiment, the line widths of the conductive lines can be equal to or larger than 20 μm, and equal to or smaller than 30 μm. In one embodiment, the line widths of the conductive lines can be larger than 0 μm, and equal to or smaller than 20 μm. In other embodiment, the line widths of the conductive lines can be reduced to about 10 μm, even in a range of larger than 0 μm and equal to or smaller than 10 μm. According to an embodiment of the disclosure, PCB (printed circuit board) traces applied by the conductive lines with high conductivity of the embodiment, which is manufactured by catalyst material formed by gravure offset printing and selective metal plating (ex: selective copper plating), have the line widths of about 10 μm, and the resistance of traces can be reduced to about 0.015Ω, and the electrical properties thereof is very similar to the conductive lines made of pure metal.

The cross-sectional profiles of the structures of conductive lines manufactured by photolithography and deriving process, printing and deriving process, and the method of the embodiment are completely different. According to the conductive lines manufactured by photolithography, the cross-sectional profile of the structure of conductive lines includes one dense metallic adhesion layer comprising metal (such as chromium, titanium . . . etc.), and a dense metal layer (such as silver, gold, copper . . . etc.) deposited on the surface of the dense metallic adhesion layer by sputtering or deposition. Thus, both layers of the conventional structure of conductive lines manufactured by photolithography are metal layers. According to the conductive lines manufactured by printing process, the cross-sectional profile of the structure of conductive lines has one layer of conductive composite of conductive fillers (such as granules of silver, copper, gold, tin . . . etc.) and polymeric material. According to the conductive lines of the embodiment, the cross-sectional profile of the structure of conductive lines has a patterned catalyst material layer (comprising polymer and catalyzer) formed on the surface of the substrate, and a dense conductive layer (such as dense metal layer) formed on the patterned catalyst material layer using electroplating or electroless plating (/chemical plating), wherein a pattern of the conductive layer 35 corresponds (ex: being substantially identical) to the patterned catalyst material layer 31.

Therefore, the cross-sectional profile of the structure of conductive lines manufactured by photolithography comprises stacked metal layers with high conductivity, but the photolithography process requires an expansive and large-scale vacuum system. Although the method for forming the conductive lines by printing process is quick, the electrical properties of the conductive lines need to be improved and the resistance to bending is bad (no stretchability as stretchable metal does). The method of manufacturing a structure of conductive lines according to the embodiment possesses several advantages such as low-production cost, rapid manufacturing procedures, high yield of production (since no notch defect typically occurs in the photolithography process would be shown in the structure of the embodiment, the problem of disconnection lines is successfully avoided), and high conductivity since the electrical properties of the embodied conductive lines are similar to the conductive lines manufactured by the photolithography process.

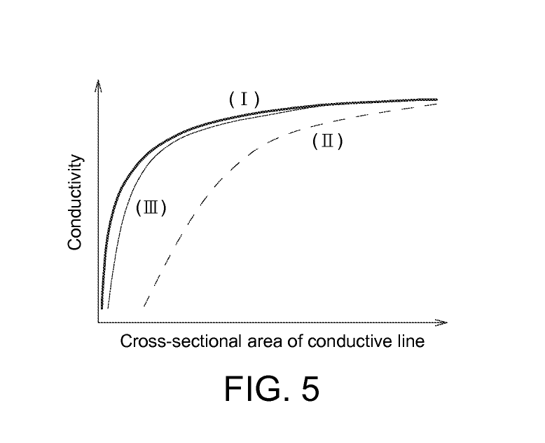

FIG. 5 shows the relationship of conductivity versus cross-sectional area of the conductive lines manufactured by the photolithography process, the printing process and the embodied manufacturing method. Curve (I) represents the relationship of conductivity versus cross-sectional area of the pure metal lines manufactured by the photolithography process. Curve (II) represents the relationship of conductivity versus cross-sectional area of the conductive lines (i.e. mixture of polymer and conductive fillers) manufactured by the printing process. Curve (III) represents the relationship of conductivity versus cross-sectional area of the conductive lines manufactured by the embodied manufacturing method. As shown in FIG. 5, a dense metal layer is formed on the substrate by photolithography (i.e. Curve (I)), and the conductivity thereof is increased with the increase of the cross-sectional area of the metal layer, and the dense metal layer has the highest conductivity. In the printing process, the conductive lines are made from a mixture of polymer and conductive fillers (i.e. Curve (II)) and the conductive fillers are melted by sintering at a high temperature, but they are not a dense metal, and the conductivity thereof is noticeably dropped with the decrease of the cross-sectional area of the conductive line. According to the disclosure, a patterned catalyst material layer (ex: not limitedly made of low-conductive or non-conductive material, and the thickness could be smaller than 3 μm) is printed on the substrate, followed by contacting one kind of metal ions as provided to the patterned catalyst material layer, such as by electroless plating or electroplating, so as to form a dense conductive layer on the patterned catalyst material layer. Accordingly, under the same cross-sectional area of the conductive lines, the cross-sectional profile of the embodied structure of conductive lines comprises a dense conductive layer. Although there is a slight differences between the electrical properties of the structures manufactured by photolithography and embodied method (i.e. Curve (I) and Curve (III)), the electrical properties of both are very similar. Also, the conductivity of the conductive lines manufactured by typical printing process (i.e. Curve (II)) is not nearly as good as that manufactured by the embodied method.

Several applicable methods according to the embodiments for manufacturing the embodied structure of the conductive lines are disclosed below. However, steps and related numerical values provided in each of the embodiments are exemplified for illustrating one of applicable procedures, not for limiting the scope of protection of the disclosure.

### First Embodiment

In the first embodiment, a catalyst material is transferred to a transferring medium, and then printed onto the surface of 7 μm polyimide (PI, i.e. the substrate) by a gravure offset printing process to form a trace pattern (i.e. a patterned catalyst material layer) having line width of 20 μm to 100 μm and film thickness smaller than 1 μm. Then, the substrate (PI) is baked in the oven at 120° C. for 30 minutes to activate the catalyzer of the catalyst material. The catalyst material contains 1 g polyacrylate-epoxy resin (type: 395, available from Chembridge), 0.1 g phenol (type: 3760, available from Chembridge) and 0.2 g silver acetate (available from SIGMA), wherein a surface tension of the catalyst material is 23.8 mN/m. Afterward, the substrate with the activated patterned catalyst material layer thereon is immersed into a plating solution containing copper sulfate to proceed the reduction reaction. In one embodiment, the plating solution contains 14.9 g/L copper sulfate, 35.1 g/L ethylenediaminetetraacetic acid (EDTA) and 10 mL/L formaldehyde. After heating at 75° C. for 30 minutes, the metal ions in the plating solution are reduced by the activated patterned catalyst material layer, and a dense conductive layer is grown on the surface of the patterned catalyst material layer, as shown in FIG. 4. According to the first embodiment, a structure of conductive lines with high conductivity can be obtained using the gravure offset printing process, and the conductivity of the embodied structure is nearly as good as the pure copper trace does.

### Second Embodiment

In the second embodiment, a metal net structure of the conductive lines is formed by a gravure offset printing process, and the sheet resistance of the metal net structure is detected. The catalyst material contains 1 g polyacrylate-epoxy resin (type: 395, available from Chembridge), 0.1 g phenol (type: 3760, available from Chembridge), 0.3 g silver acetate (available from SIGMA) and 0.1 g silver nano-particles with 20 nm diameter in average. Addition of the silver nano-particles may contribute to the increasing activity for the electroless plating, thereby increasing the plating rate of the electroless plating. After the surface tension test, it is observed that the surface tension of the catalyst material with silver nano-particles has about 1.7 mN/m more than that without addition of silver nano-particles, and reaches about 25.5 mN/m. In the second embodiment, a catalyst material is transferred to a transferring medium and then printed onto the surface of polyethylene terephthalate (PET, i.e. the substrate) by a gravure offset printing process to form a trace pattern (i.e. a patterned catalyst material layer). Then, the substrate (PET) with the catalyst material formed thereon is baked in the oven at 120° C. for 30 minutes to activate the catalyst material. Afterward, the substrate with the activated patterned catalyst material layer thereon is immersed into a plating solution (contains 14.9 g/L copper sulfate, 35.1 g/L ethylenediaminetetraacetic acid (EDTA) and 10 mL/L formaldehyde) (heated at 75° C. for 30 minutes) to grow a dense copper layer on the surface of the patterned catalyst material layer (15 minutes of electroless plating), thereby improving the conductive properties of the conductive lines. In the second embodiment, a metal net structure of the conductive lines with a line width of about 8.9 μm and a periodicity of 1000 is tested, and the experimental results indicated that the sheet resistant thereof is 1400 mΩ/□ (transmittancy 90.4%). Therefore, the metal net structure of the conductive lines manufactured by the embodied method has similar conductive properties to the pure copper. Accordingly, in the second embodiment, a metal net structure of the conductive lines (i.e. 8.9 μm of line width and 1000 of periodicity) with high conductivity can be obtained using the gravure offset printing process.

### Third Embodiment

In the third embodiment, a metal net structure of the conductive lines is formed by a gravure offset printing process, and the sheet resistance of the metal net structure is detected. The manufacturing procedures of the third embodiment are similar to that of the second embodiment, which are not redundantly repeated.

In the third embodiment, a metal net structure of the conductive lines with a line width of about 9.2 μm and a periodicity of 600 is tested, and the experimental results indicated that the sheet resistant thereof is 26.7 mΩ/□ (transmittancy 88.6%). Therefore, the metal net structure of the conductive lines manufactured by the embodied method has similar conductive properties to the pure copper. Accordingly, in the third embodiment, a metal net structure of the conductive lines (i.e. 9.2 μm of line width and 600 of periodicity) with high conductivity can be obtained using the gravure offset printing process.

### Fourth Embodiment

In the fourth embodiment, a flexible printed circuit board (FPCB) applied by the embodied structure is provided. The catalyst material is transferred to a transferring medium and then printed onto the surface of polyimide (PI, i.e. the substrate) by a gravure offset printing process to form a trace pattern (i.e. a patterned catalyst material layer). The catalyst material contains 1 g polyacrylate-epoxy resin (type: 395, available from Chembridge), 0.1 g phenol (type: 3760, available from Chembridge), 0.2 g silver acetate (available from SIGMA) and 0.21 g of surface tension modifier, wherein a surface tension of the catalyst material is 37.6 mN/m. After activation at 180° C. for 30 minutes, the substrate with the activated patterned catalyst material layer thereon is immersed into a plating solution containing copper sulfate to proceed the reduction reaction for about 30 minutes (i.e. reducing copper ions, and forming a copper layer on the patterned catalyst material layer) (the plating solution contains 14.9 g/L copper sulfate, 35.1 g/L ethylenediaminetetraacetic acid (EDTA) and 10 mL/L formaldehyde) to finish the FPCB with conductive lines. Accordingly, in the fourth embodiment, a FPCB with conductive lines with high conductivity can be obtained using the gravure offset printing process, and the line width of the conductive lines is about 10 μm.

### Fifth Embodiment

In the fifth embodiment, the patterned catalyst material layer is activated by UV irradiation. According to the fifth embodiment, the catalyst material is transferred and printed onto the surface of the substrate to form a patterned catalyst material layer, and the patterned catalyst material layer is irradiated by a UV light (365 nm wavelength of the UV light) to activate the patterned catalyst material layer. Metal ions in the plating solution are reduced by the activated patterned catalyst material layer, so as to form a dense metal layer on the surface of the patterned catalyst material layer. The catalyst material contains 1 g polyacrylate-epoxy resin (type: 395, available from Chembridge), 0.1 g phenol (type: 3760, available from Chembridge), 0.01 g TPO (photoinitiator) and 0.2 g silver acetate (available from SIGMA). In the fifth embodiment, the catalyst material is transferred and printed onto the surface of the PI substrate by a gravure offset printing process to form a trace pattern (i.e. a patterned catalyst material layer), followed by UV irradiation for about 1 minute to activate and cure the patterned catalyst material layer. After activation, the substrate with the activated patterned catalyst material layer thereon is immersed into a plating solution (containing 14.9 g/L copper sulfate, 35.1 g/L ethylenediaminetetraacetic acid (EDTA) and 10 mL/L formaldehyde) to grow a dense copper layer on the surface of the patterned catalyst material layer (15 minutes of electroless plating), thereby forming a pattern of conductive lines.

### Sixth Embodiment

In the sixth embodiment, the patterned catalyst material layer is activated by a plasma processing treatment. The patterned catalyst material layer containing materials as described in the first embodiment baked in the oven at 120° C. for 5 minutes to vaporize the solvent of the catalyst material, followed by the plasma processing treatment to activate the patterned catalyst material layer. Afterward, the substrate with the activated patterned catalyst material layer thereon is immersed into a plating solution as described in the first embodiment (i.e. contains 14.9 g/L copper sulfate, 35.1 g/L ethylenediaminetetraacetic acid (EDTA) and 10 mL/L formaldehyde) to grow a dense copper layer on the surface of the patterned catalyst material layer (15 minutes of electroless plating), thereby forming a pattern of conductive lines.

### Seventh Embodiment

In the seventh embodiment, an epoxy-based resin is adopted in the catalyst material. According to the seventh embodiment, 1 g epoxy resin (type: TC19CW10, available from TeamChem Materials Company) and 0.2 g silver acetate (available from SIGMA) are well-mixed and stirred to form a mixture of the catalyst material, and the catalyst material is transferred and printed onto the surface of the PI substrate by a gravure offset printing process to form a trace pattern (i.e. a patterned catalyst material layer), followed by activation step (as described in the first embodiment) to activate the catalyzer of the patterned catalyst material layer. Afterward, the substrate with the activated patterned catalyst material layer thereon is immersed into a plating solution as described in the first embodiment for 30 minutes, and a dense copper layer is grown on the surface of the patterned catalyst material layer.

### Eighth Embodiment

In the eighth embodiment, a phenol-based resin is adopted in the catalyst material. According to the eighth embodiment, 1 g phenol resin (type: 3760, available from Chembridge) and 0.2 g silver acetate (available from SIGMA) are well-mixed and stirred to form a mixture of the catalyst material, and the catalyst material is transferred and printed onto the surface of the PI substrate by a gravure offset printing process to form a trace pattern (i.e. a patterned catalyst material layer), followed by activation step (as described in the first embodiment) to activate the catalyzer of the patterned catalyst material layer. Afterward, the substrate with the activated patterned catalyst material layer thereon is immersed into a plating solution as described in the first embodiment for 30 minutes, and a dense copper layer is grown on the surface of the patterned catalyst material layer.

### Ninth Embodiment

In the ninth embodiment, a catalyst material comprising copper particles is adopted. According to the ninth embodiment, 1 g polyacrylate-epoxy resin (type: 395, available from Chembridge), 0.1 g phenol (type: 3760, available from Chembridge) and 3 g copper particles are well-mixed and stirred to form a mixture of the catalyst material, and the catalyst material is transferred and printed onto the surface of the PI substrate by a gravure offset printing process to form a trace pattern (i.e. a patterned catalyst material layer), followed by activation step (as described in the first embodiment) to activate the catalyzer of the patterned catalyst material layer. Afterward, the substrate with the activated patterned catalyst material layer thereon is immersed into a plating solution as described in the first embodiment for 30 minutes, and a dense copper layer is grown on the surface of the patterned catalyst material layer.

### Tenth Embodiment

In the tenth embodiment, a catalyst material comprising silver particles is adopted. According to the tenth embodiment, 1 g polyacrylate-epoxy resin (type: 395, available from Chembridge), 0.1 g phenol (type: 3760, available from Chembridge) and 5 g silver particles (20 nm of particle diameters, as the catalyzer) are well-mixed and stirred to form a mixture of the catalyst material, and the catalyst material is transferred and printed onto the surface of the PI substrate by a gravure offset printing process to form a trace pattern (i.e. a patterned catalyst material layer), followed by activation step (as described in the first embodiment) to activate the catalyzer of the patterned catalyst material layer. Afterward, the substrate with the activated patterned catalyst material layer thereon is immersed into a plating solution as described in the first embodiment for 30 minutes, and a dense copper layer is grown on the surface of the patterned catalyst material layer.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A structure of conductive lines, comprising:
a patterned catalyst material layer formed on a substrate, and the patterned catalyst material layer at least comprising:
40 wt % to 90 wt % of polymer; and
10 wt % to 60 wt % of catalyzer; and
a conductive layer, formed on the patterned catalyst material layer, and a pattern of the conductive layer corresponding to the patterned catalyst material layer, wherein the patterned catalyst material layer and the conductive layer formed thereon constitute the structure of said conductive lines, and said catalyzer comprises one or more materials selected from organic-metallic compounds, metal particles, or a combination thereof.

2. The structure of conductive lines according to claim 1, wherein a surface tension of the patterned catalyst material layer is in a range of 20 mN/m to 40 mN/m.

3. The structure of conductive lines according to claim 1, wherein line widths of the conductive lines are equal to or smaller than 30 μm.

4. The structure of conductive lines according to claim 1, wherein a boundary exists between the conductive layer and the patterned catalyst material layer, and the boundary is substantially a flat surface.

5. The structure of conductive lines according to claim 1, wherein a thickness of the patterned catalyst material layer is equal to or less than 3 μm.

6. The structure of conductive lines according to claim 1, wherein said polymer of the patterned catalyst material layer comprises one or more materials selected from acrylate resin, epoxy resin, phenol resin, or a combination thereof.

7. The structure of conductive lines according to claim 1, wherein said catalyzer of the patterned catalyst material layer comprises silver acetate, copper particles, silver particles, or a combination thereof.

8. A method of manufacturing a structure of conductive lines, comprising:
providing a substrate;
forming a patterned catalyst material layer on the substrate, and the patterned catalyst material layer at least comprising 40 wt % to 90 wt % of polymer and 10 wt % to 60 wt % of catalyzer, wherein said catalyzer comprises one or more materials selected from organic-metallic compounds, metal particles, or a combination thereof;
activating the patterned catalyst material layer; and
contacting metal ions as provided to the patterned catalyst material layer, and a conductive layer being formed on the patterned catalyst material layer.

9. The method according to claim 8, wherein a surface tension of the patterned catalyst material layer is in a range of 20 mN/m to 40 mN/m.

10. The method according to claim 8, wherein the patterned catalyst material layer is formed on the substrate by a gravure offset printing process.

11. The method according to claim 8, wherein the patterned catalyst material layer is activated by UV irradiation, thermal process, or plasma processing treatment.

12. The method according to claim 8, wherein said metal ions in an external environment are reduced by the activated patterned catalyst material layer to form the conductive layer on a surface of the patterned catalyst material layer.

13. The method according to claim 8, wherein the activated patterned catalyst material layer on the substrate is immersed into a plating solution, and the conductive layer is grown on a surface of the patterned catalyst material layer by reducing said metal ions in the plating solution.

14. The method according to claim 8, wherein line widths of the conductive lines are equal to or smaller than 30 μm.

15. The method according to claim 8, wherein a boundary exists between the conductive layer and the patterned catalyst material layer, and the boundary is substantially a flat surface.

16. The method according to claim 8, wherein a thickness of the patterned catalyst material layer is equal to or less than 3 μm.

17. The method according to claim 8, wherein said polymer of the patterned catalyst material layer comprises one or more materials selected from acrylate resin, epoxy resin, phenol resin, or a combination thereof.

18. The method according to claim 8, wherein said catalyzer of the patterned catalyst material layer comprises silver acetate, copper particles, silver particles, or a combination thereof.
